(19) United States
(12) Patent Application Publication
(10) Pub. No.: US 2024/0428985 A1
(43) Pub. Date: Dec. 26, 2024

(54) CIRCUIT DEVICE AND FILTER CIRCUIT

(71) Applicant: Murata Manufacturing Co., Ltd., Nagaokakyo-shi (JP)

(72) Inventor: Atsushi TOUJO, Nagaokakyo-shi (JP)

(21) Appl. No.: 18/822,788

(22) Filed: Sep. 3, 2024

Related U.S. Application Data
(63) Continuation of application No. PCT/JP2023/015779, filed on Apr. 20, 2023.

(30) Foreign Application Priority Data
Apr. 28, 2022 (JP) 2022-074555

(51) Int. Cl. H01F 27/29; H01F 27/02; H01F 27/28; H01F 27/32; H03H 7/09

(52) U.S. Cl. CPC H01F 27/292; H01F 27/027; H01F 27/2828; H01F 27/325; H03H 7/09

(57) ABSTRACT

A circuit device includes a coil component and a substrate. The coil component includes first and second coils whose openings overlap, a terminal connected to one end of the first coil, a terminal connected to another end of the first coil, a terminal connected to one end of the second coil, and a terminal connected to another end of the second coil. The substrate includes a power supply line electrically coupled to the terminal, a power supply line electrically coupled to the terminal, and a wiring line electrically coupled to the terminal and the terminal. The wiring line is also electrically coupled to the capacitor.

### CROSS REFERENCE TO RELATED APPLICATIONS

This application is a Continuation Application of PCT Application No. PCT/JP2023/015779, filed on Apr. 20, 2023, and claims the benefit of priority to Japanese Patent Application No. 2022-074555, filed on Apr. 28, 2022. The entire contents of each application are hereby incorporated herein by reference.

### BACKGROUND OF THE INVENTION

### 1. Field of the Invention

The present disclosure relates to circuit devices in each of which a coil component is mounted, and filter circuits.

### 2. Description of the Related Art

In an electronic device, a filter circuit that removes an unnecessary noise component from a current flowing through a conductor is used. Examples of a filter circuit used for noise removal include an electro-magnetic interference (EMI) removal filter, and a capacitor, which is a capacitance element, is used. Therefore, it has been known that due to an equivalent series inductance (ESL), which is a parasitic inductance of the capacitor, the noise removal effect of a filter circuit is decreased.

A technique that cancels an equivalent series inductance ESL of a capacitor by a negative inductance generated by magnetically coupling two coils and broadens the band for which the noise removal from a filter circuit is effective (for example, Japanese Unexamined Patent Application Publication No. 2001-160728) has been known.

However, in order to obtain a negative inductance, currents flowing through two coils to be magnetically coupled need to have the same directions. In a case where the two coils to be magnetically coupled are realized by a coil component in which wires are wound around a bobbin, as in a structure of a general transformer coil or a common mode choke coil (CMCC), when two wires wound in the same direction are used as intermediate terminals through electrically coupling of terminals of the same flange portion, currents have opposite directions and thus a negative inductance cannot be obtained.

Therefore, there has been a problem in which in the coil component including the intermediate terminals formed in the same flange portion, after a wire is wound around a bobbin from an input terminal to an intermediate terminal, the setting needs to be changed, and then the wire needs to be wound around the bobbin from the intermediate terminal to an output terminal so that the coil component is formed, as a result of which the manufacturing cost is increased. In addition, in a coil component in which the number of turns is less, when two wires are wound around a bobbin in the same direction, an interval between the coils can be relatively easily kept constant. However, in a coil component in which the setting is changed, and wires are wound around a bobbin in two steps, there is a problem in which the interval between the coils cannot be easily kept constant, and a mutual inductance is not stabilized.

### SUMMARY OF THE INVENTION

Example embodiments of the present invention provide circuit devices that are each able to provide a filter circuit including a coil component whose manufacturing cost is low and in which a mutual inductance is stabilized, and filter circuits.

A circuit device according to example embodiments of the present invention includes a coil component, and a substrate on which the coil component is mounted. The coil component includes a first coil, a second coil whose opening overlaps with an opening of the first coil when viewed in an opening direction of the first coil, a first terminal connected to one end of the first coil, a second terminal connected to another end of the first coil, a third terminal connected to one end of the second coil, and a fourth terminal connected to another end of the second coil. A direction of a magnetic field generated in the first coil when a current flows from the first terminal to the second terminal is the same as a direction of a magnetic field generated in the second coil when a current flows from the third terminal to the fourth terminal. The substrate includes a first wiring line electrically coupled to the first terminal, a second wiring line electrically coupled to the fourth terminal, and a third wiring line electrically coupled to the second terminal and the third terminal, and the third wiring line is also electrically coupled to a capacitor.

A filter circuit according to an example embodiment of the present invention includes a circuit device according to an example embodiment of the present invention, and a capacitor electrically coupled to a third wiring line of the circuit device.

According to example embodiments of the present invention, since a third wiring line electrically coupled to a second terminal and a third terminal of a coil component is included, and the third wiring line is also electrically coupled to a capacitor, a filter circuit including a coil component whose manufacturing cost is low and in which a mutual inductance is stabilized can be provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a plan view of a circuit device according to a first example embodiment of the present invention.

FIG. 2 is a perspective view of a coil component according to the first example embodiment of the present invention.

FIG. 3 is a circuit diagram of a filter circuit according to the first example embodiment of the present invention.

FIG. 4 is a plan view of a circuit device according to a modification 1-1 of an example embodiment of the present invention.

FIG. 5 is a plan view of a circuit device according to a modification 1-2 of an example embodiment of the present invention.

FIG. 6 is a perspective view of a circuit device according to a second modification of an example embodiment of the present invention.

FIG. 7 is a perspective view of a coil component according to a third modification of an example embodiment of the present invention.

FIGS. 8A and 8B are side views of the coil component according to the third modification.

FIG. 9 is a plan view of a circuit device according to a second example embodiment of the present invention.

FIG. 10 is a perspective view of a coil component according to the second example embodiment of the present invention.

### DETAILED DESCRIPTION OF THE EXAMPLE EMBODIMENTS

Example embodiments of the present invention will be described in detail below with reference to the drawings.

### First Example Embodiment

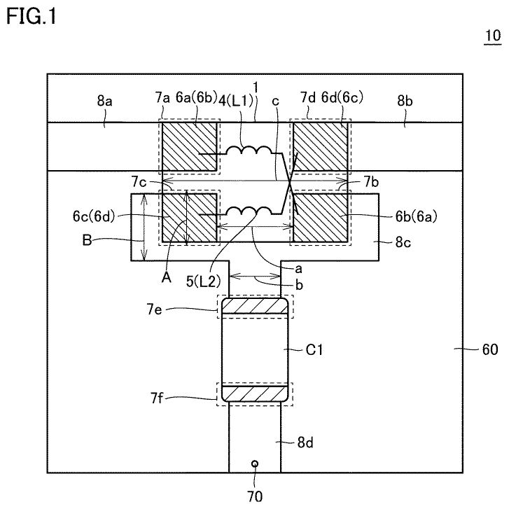

Hereinafter, a circuit device according to a first example embodiment of the present invention will be described. FIG. 1 is a plan view of a circuit device 10 according to the first example embodiment. The circuit device 10 is a filter circuit preferably used for, for example, noise removal from power supply lines 8a and 8b and in which a coil component 1 including two coils magnetically coupled to cancel a parasitic inductance of a capacitor C1 is mounted. The circuit device 10 is not limited to a filter circuit used for noise removal from the power supply lines 8a and 8b, and may be, for example, a filter circuit used for noise removal from other signal lines, or the like.

The coil component 1 mounted in the circuit device 10 includes two wires wound around a bobbin in the same direction as described later. Therefore, compared to a case in which a coil component is made of a wire wound around a bobbin such that a winding direction from an input terminal to an intermediate terminal is opposite to a winding direction from the intermediate terminal to an output terminal, in the coil component 1, two wires can be wound together, and thus the manufacturing cost is low. In addition, in the coil component 1, since two wires are wound around a bobbin in the same direction, the interval between coils is relatively easily kept constant, and a mutual inductance is stabilized. The coil component 1 having a configuration of a wound-wire coil in which a wire is wound around a bobbin will be described as an example, but coil components having other configurations may be provided.

In the coil component 1, two wires are wound around a bobbin in the same direction, and thus the coil component 1 includes a terminal 6a (a first terminal) connected to one end of a first wire 4, a terminal 6b (a second terminal) connected to another end of the first wire 4, a terminal 6c (a third terminal) connected to one end of a second wire 5, and a terminal 6d (a fourth terminal) connected to another end of the second wire 5. That is, the coil component 1 includes four terminals including the terminals 6a to 6d. The four terminals (the terminals 6a to 6d) are preferably provided at four corners of the coil component 1. The first wire 4 wound around the bobbin defines a first coil L1, and the second wire 5 wound around the bobbin defines a second coil L2.

In a filter circuit, a coil component that cancels a parasitic inductance of a capacitor may functionally include three terminals (an input terminal, an intermediate terminal, and an output terminal). However, in a general electronic component, a rectangular or substantially rectangular parallelepiped shape is often used due to considerations of ease of manufacturing, and in the coil component as well, a rectangular or substantially rectangular parallelepiped shape is often used, and a terminal not connected to another element (non-connection (NC) terminal) is provided in terms of mechanical strength so that four terminals are included. Even when a coil component including four terminals including an NC terminal is provided, only three terminals are functionally used, and thus a direction of the coil component when a substrate 60 is mounted in the coil component becomes a problem. Therefore, a mark indicating a direction needs to be provided in the coil component, and there are factors of an increase in manufacturing cost, such as the direction of the coil component having to be arranged at the time of characteristic selecting or taping. On the other hand, since the coil component 1 according to the first example embodiment does not require an NC terminal, the direction does not become a problem as described later.

As illustrated in FIG. 1, the coil component 1 has a rectangular or substantially rectangular shape when viewed in a direction perpendicular or substantially perpendicular to the substrate 60. The terminals 6a to 6d are provided on the same plane of the coil component 1. The terminals 6a to 6d are located such that a direction from the terminal 6a to the terminal 6b crosses a direction from the terminal 6c to the terminal 6d.

In the circuit device 10, wiring patterns of the power supply lines 8a and 8b are provided on a surface of the substrate 60, and the coil component 1 is mounted in series with respect to the power supply lines 8a and 8b. The power supply line 8a (a first wiring line) is provided with an electrode 7a (a first electrode) electrically coupled to the terminal 6a of the coil component 1 to input a current from the power supply line 8a to the coil component 1. The terminal 6a electrically coupled to the electrode 7a defines and functions as an input terminal of the coil component 1. On the other hand, the power supply line 8b (a second wiring line) is provided with an electrode 7d (a fourth electrode) electrically coupled to the terminal 6d of the coil component 1 to output a current from the coil component 1 to the power supply line 8b. The terminal 6d electrically coupled to the electrode 7d functions as an output terminal of the coil component 1.

The substrate 60 includes a plurality of insulating layers being stacked and preferably includes, for example, a low-temperature co-fired ceramic material, a glass epoxy resin, or the like. On a surface of the substrate 60, a wiring pattern such as the power supply line 8a, an electrode to couple a component such as the coil component 1 or the capacitor C1, and the like are formed, and each of such elements includes a metal material generally used as an electrode material such as, for example, Cu, Ag, Al, or the like. For example, when the substrate 60 is a glass epoxy resin, a wiring pattern includes Cu on the glass epoxy resin, and an insulating resin is further formed on the glass epoxy resin including the wiring pattern. The electrode to electrically couple a component, such as the coil component 1 to be mounted or the capacitor C1, to the wiring pattern is preferably a portion formed by removing the insulating resin on the wiring pattern. The electrode on the wiring pattern is a place where Cu of the wiring pattern and a terminal of a component are electrically coupled by soldering, for example.

Moreover, in the circuit device 10, the capacitor C1 is connected in series to the terminals 6b and 6c that define and function as intermediate terminals of the coil component 1. The substrate 60 is preferably provided with a wiring line 8c (a third wiring line) that connects an electrode 7b (a second electrode) to connect the terminal 6b and an electrode 7c (a third electrode) to connect the terminal 6c with a straight line. As illustrated in FIG. 1, since the wiring line 8c connects the terminal 6b and the terminal 6c at the shortest distance, compared to a case where a wiring line connected to the terminal 6b and a wiring line connected to the terminal 6c are separately connected by a wiring line, a parasitic inductance can be reduced, and most of the negative mutual inductance generated in the coil component 1 can be used to cancel out the parasitic inductance. Through changing of the distance of the wiring line connecting the terminal 6b and the terminal 6c (not illustrated), the parasitic inductance can be increased or decreased, and thus the negative mutual inductance as the entire circuit can be adjusted.

The wiring line 8c is provided with an electrode 7e (a fifth electrode) to be electrically coupled to the capacitor C1. In the circuit device 10 illustrated in FIG. 1, when viewed in a direction perpendicular or substantially perpendicular to the substrate 60, the shape of the wiring line 8c is a T shape. Specifically, when viewed in the direction perpendicular or substantially perpendicular to the substrate 60, the T shape of the wiring line 8c is defined by a portion connecting, with a straight line, a connection portion (the electrode 7b) between the wiring line 8c and the terminal 6b to a connection portion (the electrode 7c) between the wiring line 8c and the terminal 6c, and a portion extending from a central portion of the portion connecting the above-described two connection portions with a straight line to a connection portion (the electrode 7e) of the capacitor C1. That is, a wiring direction of a portion of the wiring line 8c connecting the capacitor C1 is perpendicular to a wiring direction of the portion of the wiring line 8c connecting the electrode 7b and the electrode 7c with a straight line. Note that the portion of the wiring line 8c connecting the capacitor C1 and the portion of the wiring line 8c connecting the electrode 7b and the electrode 7c with a straight line may be integrally provided or provided separately.

Therefore, since the wiring direction of the portion of the wiring line 8c connecting the capacitor C1 with respect to opening directions of the first coil L1 and the second coil L2 is perpendicular or substantially perpendicular, the opening directions of the first coil L1 and the second coil L2 and an arrangement direction of the capacitor C1 (a direction connecting electrodes of the capacitor C1) becomes perpendicular or substantially perpendicular. Since the capacitor C1 is not arranged in a direction in which magnetic fields of the first coil L1 and the second coil L2 are generated, an influence of the capacitor C1 on the magnetic fields of the first coil L1 and the second coil L2 can be reduced. Since the coil component 1 is a small-sized chip component, in general, heat dissipation from the substrate 60 side on which the coil component 1 is mounted becomes dominant. Therefore, the wiring line 8c provided so as to extend over the terminals 6b and 6c functioning as intermediate terminals of the coil component 1 can improve the heat dissipation from the coil component 1 and can increase a current flowing through the coil component 1. From the perspective of heat dissipation, a width B of the wiring line 8c may be, for example, about two times of a width A of the electrode 7b or the electrode 7c. As the width B of the wiring line 8c is increased, the heat dissipation is improved, but the distance between the coil component 1 and the capacitor C1 is increased, and a parasitic inductance caused by the wiring line from the coil component 1 to the capacitor C1 is increased. Therefore, the width B of the wiring line 8c is, for example, preferably approximately 1.3 to approximately 4 times of the width A of the electrode 7b or the electrode 7c.

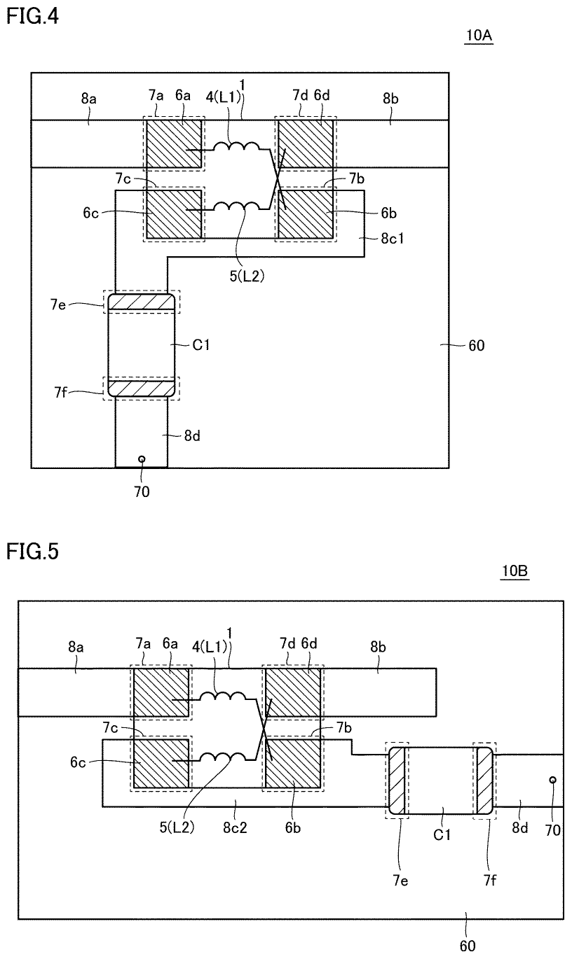

As described above, when the width B of the wiring line 8c is increased, the heat dissipation is improved, but components other than the coil component 1 and the capacitor C1 cannot be disposed, and the flexibility in designing the substrate 60 is decreased. Since a coil included in the coil component 1 is designed to allow a constant current to flow therethrough, heat generation does not particularly become a problem, but a path through which a current flows from the electrode 7c to the electrode 7b through the wiring line 8c provided in the substrate 60 becomes a problem with heat generation. Therefore, a heat dissipation countermeasure may be provided in a section between the electrode 7c and electrode 7b. That is, when the wiring line 8c has a T shape as illustrated in FIG. 1, a length b of a portion of the wiring line 8c connected to the capacitor C1 is preferably longer than a distance a between the electrode 7c and the electrode 7b. On the other hand, the length b of the portion of the wiring line 8c connected to the capacitor C1 is preferably shorter than a length c of the coil component 1, and compared to a case in which the width B of the wiring line 8c is increased, a space where components are freely disposed in the left and right direction of the capacitor C1 in the figure can be ensured. The same applies to a wiring line 8c1 illustrated in FIG. 4 and a wiring line 8c2 illustrated in FIG. 5 described later.

The capacitor C1 is connected in series to the wiring line 8c and electrically coupled to a wiring line 8d (a fourth wiring line) on a side opposite to a side electrically coupled to the wiring line 8c. The wiring line 8d is provided with an electrode 7f to be electrically coupled to the capacitor C1. The wiring line 8d is grounded through a ground electrode 70. The capacitor C1 is mounted between the wiring line 8c and the wiring line 8d, and thus the terminals 6b and 6c between two coils (the first coil L1 and the second coil L2) included in the coil component 1 and the ground electrode 70 (GND) are electrically coupled. The ground electrode 70 is an electrode electrically coupled to a ground potential and includes, for example, a conductive via electrically coupled to a ground potential disposed in an inner layer of the substrate 60.

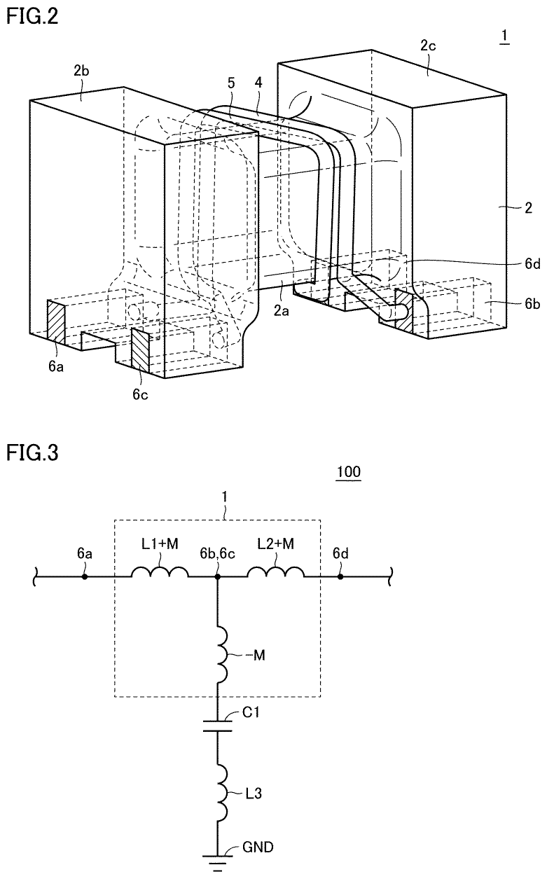

Next, the coil component 1 mounted in the circuit device 10 will be described. FIG. 2 is a perspective view of the coil component 1 according to the first example embodiment. The coil component 1 includes a bobbin 2, a first wire 4, and a second wire 5. The bobbin 2 includes a body portion 2a around which a wire is wound and flange portions 2b and 2c provided at both ends of the body portion 2a. The bobbin 2 is preferably made of, for example, a non-conductive material, specifically, a nonmagnetic substance such as, for example, alumina, a magnetic substance such as Ni—Zn based ferrite, a resin, or the like. When the bobbin 2 is made of a resin, the bobbin 2 is made of, for example, a resin including a magnetic powder such as a metal powder or a ferrite powder, a resin including a nonmagnetic powder such as a silica powder, a resin not including a filler such as a powder, or the like.

When the size of the coil component 1 is about 2.0 mm×about 1.25 mm, the body portion 2a of the bobbin 2 is a prism of about 1.0 mm×about 1.0 mm, for example. In the present disclosure, the body portion 2a is described as a prism, but may be a column or a polygonal prism, for example. In the coil component 1, the first wire 4 and the second wire 5 are directly wound around the body portion 2a. The first wire 4 and the second wire 5 are, for example, a copper wire.

In order to stabilize a mutual inductance in the coil component 1, opening diameters of the first coil L1 and the second coil L2 and a coil interval between the first coil L1 and the second coil L2 need to be maintained constant or substantially constant. Therefore, the first wire 4 and the second wire 5 are simultaneously wound around the body portion 2a in the same direction and define the coil component 1. Moreover, as illustrated in FIG. 2, the first wire 4 is wound around the body portion 2a one time and defines the first coil L1, and the second wire 5 is wound around the body portion 2a one time and defines the second coil L2. In a strict sense, the first wire 4 is wound around three surfaces of the body portion 2a from the terminal 6a to the terminal 6b, which is about a ¾ turn, and the second wire 5 is wound around five surfaces of the body portion 2a from the terminal 6c to the terminal 6d, which is about a 5/4 turn. Here, winding a wire around the body portion 2a one time means that the number of turns of winding the wire around the body portion 2a is one and includes winding the wire around the body portion 2a by about a ¾ turn and about a 5/4 turn.

Next, a terminal that fixes the first wire 4 and a terminal that fixes the second wire 5 will be described. As illustrated in FIG. 2, the flange portions 2b and 2c provided on both sides of the bobbin 2 are provided with the terminals 6a and 6b connected to end portions of the first wire 4 and the terminal 6c and 6d connected to end portions of the second wire 5. Specifically, the flange portion 2b is provided with the terminals 6a and 6c, and the flange portion 2c is provided with the terminals 6b and 6d, respectively.

The terminals 6a to 6d are baked with an Ag paste, for example, and plated with Ni plating or Sn plating, for example. Therefore, the end portions of the first wire 4 are pressed to the terminals 6a and 6b, and the end portions of the second wire 5 are pressed to the terminals 6c and 6d to be thermocompression-bonded or laser-welded so that the wires are fixed to the terminals, respectively. It is needless to say that the fixing method of the wires and the terminals is not limited thereto, and a fixing method of bonding using, for example, a metal terminal, crimping, soldering, or the like may be used. Moreover, after the wires and the terminals are crimped using a metal terminal and fixed, for example, laser welding may be further applied.

In the coil component 1, in the terminals 6a to 6d provided on the same surface of the coil component 1, the position of the terminal 6a provided in the flange portion 2b and the position of the terminal 6d provided in the flange portion 2c are on the same side (an upper side in FIG. 1). Therefore, as illustrated in FIG. 2, the first wire 4 and the second wire 5 wound around the body portion 2a in the same direction are connected to the terminals 6a to 6d so that the first coil L1 and the second coil L2 are arranged so as to cross each other as illustrated in FIG. 1.

When the first coil L1 and the second coil L2 are arranged to cross each other, a current can flow through the first coil L1 from either the terminal 6a or the terminal 6b, and a current can flow through the second coil L2 from either the terminal 6c or the terminal 6d, there is no difference between characteristics due to the direction of the coil component 1. That is, in the coil component 1, the direction of the coil component 1 does not become a problem when the substrate 60 is mounted. Therefore, a mark indicating a direction does not have to be provided in the coil component 1, and the direction of the coil component does not have to be arranged at the time of characteristic selecting or taping, and thus the manufacturing cost can be decreased.

Specifically, when the direction of the coil component 1 is rotated by about 180° (when indicated by reference numerals surrounded by parentheses in FIG. 1), the terminal 6b of the coil component 1 is electrically coupled to the power supply line 8a, the terminal 6c of the coil component 1 is electrically coupled to the power supply line 8b, the terminals 6a and 6d function as intermediate terminals of the coil component 1 and are connected to the electrodes 7b and 7c of the wiring line 8c. Since the first coil L1 and the second coil L2 are disposed so as to cross each other, the terminals 6a and 6b serving as input terminals and the terminals 6d and 6c defining and functioning as output terminals are linearly arranged as illustrated in FIG. 1, and thus usability is improved when the input terminals and the output terminals are connected to other devices.

When the coil component 1 is mounted on the substrate 60, the opening directions of the first coil L1 and the second coil L2 are parallel or substantially parallel to a surface of the substrate 60 on which the coil component 1 is mounted.

FIG. 3 is a circuit diagram of a filter circuit 100 according to the first example embodiment. Specifically, the filter circuit 100 is an EMI removal filter circuit and a third T-shaped LC filter circuit. In the present disclosure, as a configuration of the filter circuit 100, a third T-shaped LC filter circuit is used for explanation, but the same configuration can be applied to a fifth T-shaped LC filter circuit or a higher T-shaped LC filter circuit. First, as illustrated in FIG. 3, the filter circuit 100 includes the coil component 1 and the capacitor C1.

As illustrated in FIG. 3, the capacitor C1 is preferably connected in series between the terminals 6b and 6c serving as intermediate terminals and a ground electrode (GND). The capacitor C1 may be one, but a redundant circuit configuration in which two capacitors are connected in series may be adopted assuming a case of being mounted in a vehicle.

The capacitor C1 is not limited to being a multilayer ceramic capacitor including barium titanate (BaTiO3) as a main component, and may be, for example, a multilayer ceramic capacitor including another material as a main component or other types of capacitors, which are not a multilayer ceramic capacitor, such as an aluminum electrolytic capacitor.

The capacitor C1 connected to the coil component 1 includes an inductor L3 which is provided by a parasitic inductance (an equivalent series inductance (ESL)). Therefore, as illustrated in FIG. 3, the filter circuit 100 becomes equivalent to a circuit configuration in which the inductor L3 is connected in series to the capacitor C1.

In addition to the capacitor C1, the first coil L1 and the second coil L2 are connected to the terminals 6b and 6c. The first coil L1 and the second coil L2 are magnetically coupled and generate a negative inductance component (a mutual inductance M). Through using of the negative inductance component, the parasitic inductance (the inductor L3) of the capacitor C1 can be cancelled, and the inductance component of the capacitor Cl can become small in appearance. In FIG. 3, the mutual inductance M (−M) to cancel the inductor L3 is connected in series to the capacitor C1 and is illustrated as an equivalent circuit in which the mutual inductance M (+M) is added to each of the first coil L1 and the second coil L2.

In the filter circuit 100 including the capacitor C1, the first coil L1, and the second coil L2, a negative inductance component by the mutual inductance M of the first coil L1 and the second coil L2 cancels the parasitic inductance of the capacitor C1, and thus the noise removal effect in a high frequency band can be improved.

Since the parasitic inductance by the wiring line 8c that electrically couples the terminal 6b and the terminal 6c of the coil component 1 is generated in series with the capacitor C1 and the inductor L3, which is a parasitic inductance of the capacitor C1, changing the parasitic inductance through changing of the length of the wiring line 8c enables adjustment for cancelling out the inductor L3 and the mutual inductance M.

As described above, the circuit device 10 according to the first example embodiment includes the coil component 1 and the substrate 60 on which the coil component 1 is mounted. The coil component 1 includes the first coil L1, the second coil L2 whose opening overlaps with an opening of the first coil L1 when viewed in an opening direction of the first coil L1, the terminal 6a connected to one end of the first coil L1, the terminal 6b connected to another end of the first coil L1, the terminal 6c connected to one end of the second coil L2, and the terminal 6d connected to another end of the second coil L2. A direction of a magnetic field generated in the first coil L1 when a current flows from the terminal 6a to the terminal 6b is the same as a direction of a magnetic field generated in the second coil L2 when a current flows from the terminal 6c to the terminal 6d. The substrate 60 includes the power supply line 8a electrically coupled to the terminal 6a, the power supply line 8b electrically coupled to the terminal 6d, and the wiring line 8c electrically coupled to the terminal 6b and the terminal 6c. The wiring line 8c is also electrically coupled to the capacitor C1.

As a result, the circuit device 10 according to the first example embodiment includes the wiring line 8c electrically coupled to the terminal 6b and the terminal 6c of the coil component 1, and the wiring line 8c is also electrically coupled to the capacitor C1, and thus the filter circuit 100 using the coil component 1 whose manufacturing cost is low and in which a mutual inductance is stabilized can be provided.

In addition, the filter circuit 100 according to the first example embodiment includes the above-described circuit device 10 and the capacitor C1 electrically coupled to the wiring line 8c of the circuit device 10. As a result, the filter circuit 100 can cancel a parasitic inductance of the capacitor C1 and improve the noise removal effect in a high frequency band.

### First Modification

In the circuit device 10 illustrated in FIG. 1, the shape of the wiring line 8c being a T shape has been described, but is not limited thereto, and a portion of a wiring line connecting the capacitor C1 may be provided in a portion other than the central portion of the wiring line 8c. FIG. 4 is a plan view of a circuit device 10A according to a modification 1-1 of an example embodiment of the present invention. FIG. 5 is a plan view of a circuit device 10B according to a modification 1-2 of an example embodiment of the present invention. In the circuit devices 10A and 10B illustrated in FIGS. 4 and 5, the same or corresponding elements as those of the circuit device 10 illustrated in FIG. 1 are denoted by the same reference numerals, and detailed description is omitted.

In the circuit device 10A illustrated in FIG. 4, the shape of the wiring line 8c1 is, for example, preferably an L shape when viewed in a direction perpendicular or substantially perpendicular to the substrate 60. Specifically, in the wiring line 8c1, a portion of a wiring line connecting the capacitor C1 extends from a long side on the electrode 7c side of a portion connecting the electrode 7b and the electrode 7c with a straight line so that an L shape is formed. The capacitor C1 is connected in series to the wiring line 8cl and is electrically coupled to the wiring line 8d on a side opposite to a side electrically coupled to the wiring line 8c1. In the wiring line 8c1, the portion of the wiring line connecting the capacitor C1 may extend from a long side on the electrode 7b side of the portion connecting the electrode 7b and the electrode 7c with a straight line so that an L shape is provided.

In the circuit device 10B illustrated in FIG. 5, the shape of the wiring line 8c2 is, for example, preferably an I shape when viewed in the direction perpendicular or substantially perpendicular to the substrate 60. Specifically, in the wiring line 8c2, a portion of a wiring line connecting the capacitor C1 extends from a short side on the electrode 7b side of a portion connecting the electrode 7b and the electrode 7c with a straight line so that an I shape is provided. The capacitor C1 is connected in series to the wiring line 8c2 and is electrically coupled to the wiring line 8d on a side opposite to a side electrically coupled to the wiring line 8c2. In the wiring line 8c2, the portion of the wiring line connecting the capacitor C1 may extend from a short side on the electrode 7c side of the portion connecting the electrode 7b and the electrode 7c with a straight line so that an I shape is provided.

As illustrated in FIGS. 4 and 5, the portion of the wiring line connecting the capacitor C1 can be connected to various portions. As a result, the position at which the capacitor C1 is mounted can be changed freely, and thus the flexibility of design by a manufacturer who adopts the circuit device is improved.

### Second Modification

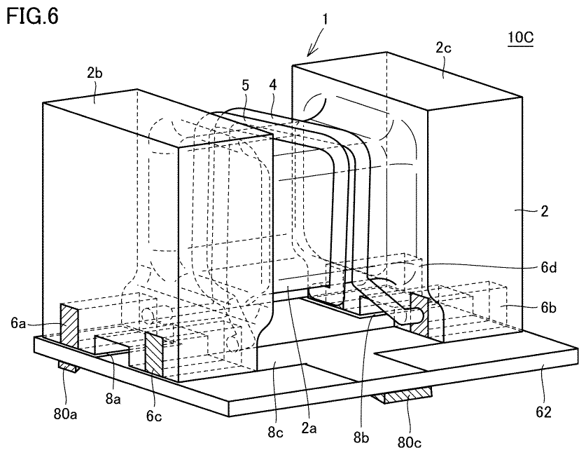

As illustrated in FIG. 1, the circuit device 10 in which the coil component 1 and the capacitor C1 are mounted on the substrate 60 provided with the power supply lines 8a and 8b and the wiring lines 8c and 8d has been described, but the circuit device 10 is not limited thereto, and may be one component defined by a coil component to which an interposer substrate provided with a power supply line and a wiring line is attached. FIG. 6 is a perspective view of a circuit device according to a second modification of an example embodiment of the present invention. In a circuit device 10C illustrated in FIG. 6, the same or corresponding elements as those of the circuit device 10 illustrated in FIG. 1 are denoted by the same reference numerals, and detailed description is omitted.

The circuit device 10C illustrated in FIG. 6 is one component provided through attaching of an interposer substrate 62 provided with the power supply lines 8a and 8b and the wiring line 8c to a surface of the coil component 1 on which the terminals 6a to 6d are provided. The power supply lines 8a and 8b and the wiring line 8c are provided on a front surface of the interposer substrate 62 in contact with the coil component 1, and electrodes electrically coupled to the power supply lines 8a and 8b and the wiring line 8c by through electrodes (not illustrated) are formed on a rear surface.

Specifically, on the rear surface of the interposer substrate 62, an electrode 80a electrically coupled to the power supply line 8a by a through electrode, an electrode (not illustrated) electrically coupled to the power supply line 8b by a through electrode, and an electrode 80c electrically coupled to the wiring line 8c by a through electrode are formed. The electrode 80a is connected to a power supply line of a device in which the circuit device 10C is mounted, and the electrode 80c is connected to the capacitor C1.

### Third Modification

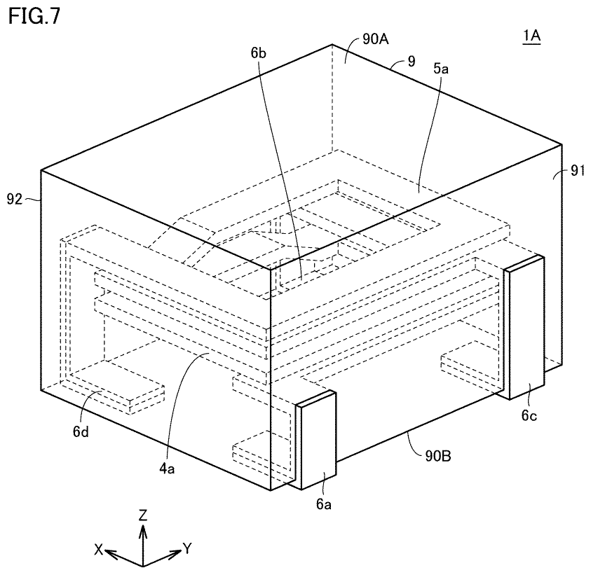

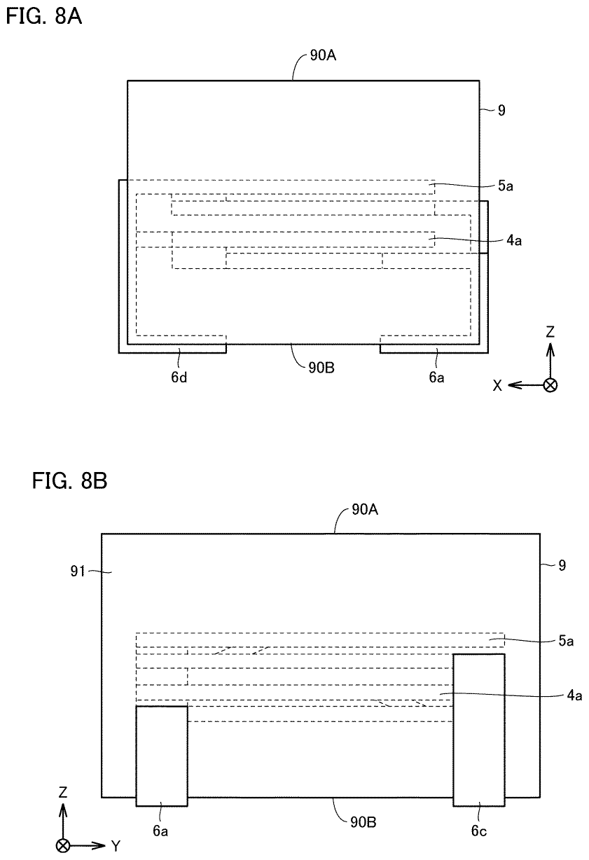

In the above-described first example embodiment, as illustrated in FIG. 2, the coil component 1 having a configuration in which the first wire 4 and the second wire 5 are wound around the bobbin 2 has been described. However, the coil component mounted in the circuit device 10 is not limited to a coil component in which a wire is wound around a bobbin, and may be a coil component having a configuration in which a coil defined by, for example, a metal plate or a metal wire is sealed with resin. FIG. 7 is a perspective view of a coil component 1A according to a third modification. FIGS. 8A and 8B are side views of the coil component 1A according to the third modification of an example embodiment of the present invention. FIG. 8A is a side view in an X-Z plane of the coil component 1A, and FIG. 8B is a side view in a Y-Z plane of the coil component 1A.

The coil component 1A includes a coil portion 4a (the first coil L1) and a coil portion 5a (the second coil L2) in a housing 9. The coil portion 4a includes a rectangular or substantially rectangular opening and is disposed parallel or substantially parallel to a main surface 90A (a first main surface) inside the housing 9. In addition, the coil portion 4a preferably includes a spiral structure that is made of a punched metal plate, a portion of which is inclined, so as to be wound about 1.5 times, a portion extended from a side surface 91 (a first side surface) of the housing 9 defines the terminal 6a (the first terminal), and a portion extended from a side surface 92 (a second side surface) of the housing 9 defines the terminal 6b (the second terminal). The coil portion 5a includes a rectangular or substantially rectangular opening and is disposed parallel or substantially parallel to the main surface 90A and above the coil portion 4a inside the housing 9. In addition, the coil portion 5a of an example embodiment of the present invention includes a spiral structure that is made of a punched metal plate, a portion of which is inclined, so as to be wound about 1.5 times, a portion extended from the side surface 91 of the housing 9 defines the terminal 6c (the third terminal), and a portion extended from the side surface 92 defines the terminal 6d (the fourth terminal).

The terminals 6a to 6d extend to a main surface 90B and are provided on the same plane of the coil component 1A. The terminals 6a to 6d are arranged such that the direction from the terminal 6a to the terminal 6b and the direction from the terminal 6c to the terminal 6d cross each other. That is, the terminals 6a to 6d on the main surface 90B are arranged in a staggered pattern. When the coil component 1A is mounted on the substrate 60 such that the terminals 6a to 6d provided on the main surface 90B are electrically coupled to the electrodes 7a to 7d provided on the substrate 60, opening directions of the coil portions 4a and 5a are perpendicular or substantially perpendicular to the substrate 60, and the arrangement relation with the capacitor C1 connected to the terminal 6c of the coil portion 4a and the terminal 6d of the coil portion 5a is also perpendicular or substantially perpendicular.

The housing 9 fixes a relative position between the coil portion 4a and the coil portion 5a and is preferably made of, for example, a mold resin. Specifically, the mold resin is preferably made of, for example, an epoxy resin, a silicone resin, or a liquid crystal polymer to which a silica filler is added, or various types of resin in which a metal magnetic substance is mixed.

The coil portion 4a and the terminals 6a and 6b may be defined by one metal plate or one metal wire, or the coil portion 4a and the terminals 6a and 6b may be defined by separate metal plates or metal wires. Similarly, the coil portion 5a and the terminals 6c and 6d may be integrally provided one metal plate or one metal wire, or the coil portion 5a and the terminals 6c and 6d may be defined by separate metal plates or metal wires.

### Second Example Embodiment

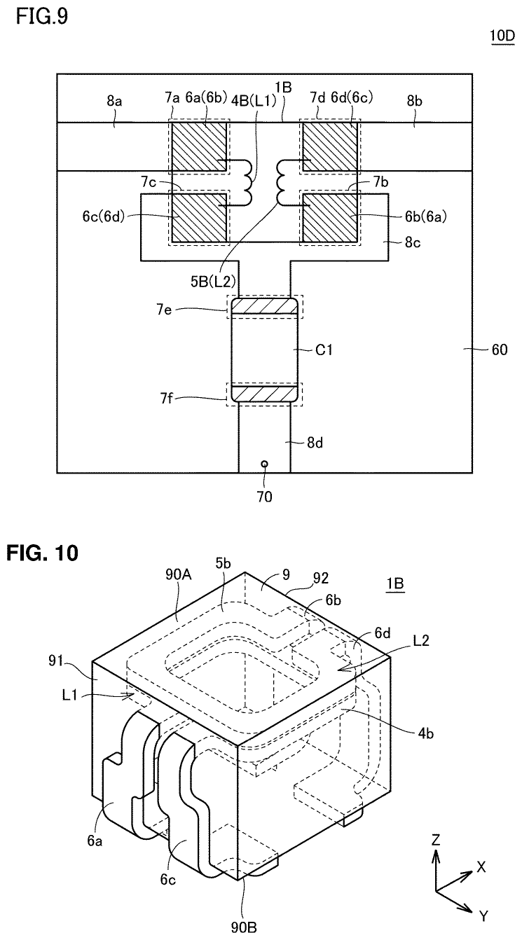

In the first example embodiment, the coil component 1 mounted in the circuit device 10 having a configuration in which connection positions of both ends of the first coil L1 and connection positions of both ends of the second coil L2 cross each other has been described, but the configuration is not limited thereto. In a second example embodiment of the present invention, a configuration in which, in the coil component, connection positions of both ends of the first coil L1 and connection positions of both ends of the second coil L2 do not cross each other will be described. FIG. 9 is a plan view of a circuit device 10D according to the second example embodiment. In the circuit device 10D illustrated in FIG. 9, the same or corresponding elements as those of the circuit device 10 illustrated in FIG. 1 are denoted by the same reference numerals, and detailed description is not repeated.

In the circuit device 10D illustrated in FIG. 9, the configuration of a coil component 1B mounted on the substrate 60 is different. Specifically, the coil component 1B includes the terminal 6a (the first terminal) connected to one end of a first wiring line 4B defining the first coil L1, the terminal 6c (the second terminal) connected to another end of the first wiring line 4B, the terminal 6b (the third terminal) connected to one end of a second wiring line 5B defining the second coil L2, and the terminal 6d (the fourth terminal) connected to another end of the second wiring line 5B. The first wiring line 4B of the first coil L1 is connected to the electrodes 7a and 7c side provided on the substrate 60, and the second wiring line 5B of the second coil L2 is connected to the electrodes 7b and 7d side. Therefore, in the coil component 1B, connection positions of both ends of the first coil L1 and connection positions of both ends of the second coil L2 are arranged so as not to cross each other.

The coil component 1B may have a configuration in which the first wire and the second wire are wound around a bobbin or a configuration in which a coil defined by a metal plate or a metal wire is sealed with resin. FIG. 10 is a perspective view of the coil component 1B according to the second example embodiment. In the coil component 1B illustrated in FIG. 10, the same or corresponding elements as those of the coil component 1A illustrated in FIG. 7 are denoted by the same reference numerals, and detailed description is not repeated.

The coil component 1B includes a coil portion 4b (the first coil L1) and a coil portion 5b (the second coil L2) in the housing 9. The coil portion 4b includes a rectangular or substantially rectangular opening, is parallel or substantially parallel to the main surface 90A (the first main surface), and embedded in the housing 9. In addition, one portion, of the coil portion 4b, extended from the side surface 91 (the first side surface) of the housing 9 defines the terminal 6a, and another portion defines the terminal 6c. The coil portion 4b, the terminal 6a, and the terminal 6c are defined by a punched metal plate and corresponds to the first wiring line 4B illustrated in FIG. 9.

The coil portion 5b includes a rectangular or substantially rectangular opening, is parallel or substantially parallel to the main surface 90A, and disposed above the coil portion 4a inside the housing 9. In addition, one portion, of the coil portion 5a, extended from the side surface 92 of the housing 9 defines the terminal 6b, and another portion defines the terminal 6d. Note that the coil portion 5b, the terminal 6b, and the terminal 6d are defined by a punched metal plate and corresponds to the second wiring line 5B illustrated in FIG. 9.

The terminals 6a to 6d extend to the main surface 90B. The terminals 6a to 6d provided on the main surface 90B are electrically coupled to the electrodes 7a to 7d provided on the substrate 60. In the coil component 1B, the direction from the terminal 6a to the terminal 6c and the direction from the terminal 6d to the terminal 6b do not cross each other, and the terminals 6a to 6d are disposed on the main surface 90B. Therefore, in the circuit device 10D in which the substrate 60 and the coil component 1B are combined, the coil component 1B can be mounted on the substrate 60 regardless of the direction of the coil component 1B, and a filter circuit using a negative mutual inductance can be configured.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit device comprising:
a coil component; and
a substrate on which the coil component is mounted; wherein the coil component includes:
a first coil;
a second coil whose opening overlaps with an opening of the first coil when viewed in an opening direction of the first coil;
a first terminal connected to one end of the first coil;
a second terminal connected to another end of the first coil;
a third terminal connected to one end of the second coil; and
a fourth terminal connected to another end of the second coil;
a direction of a magnetic field generated in the first coil when a current flows from the first terminal to the second terminal is the same as a direction of a magnetic field generated in the second coil when a current flows from the third terminal to the fourth terminal;
the substrate includes:
a first wiring line electrically coupled to the first terminal;
a second wiring line electrically coupled to the fourth terminal; and
a third wiring line electrically coupled to the second terminal and the third terminal; and
the third wiring line is also electrically coupled to a capacitor.

2. The circuit device according to claim 1, wherein
the coil component has a rectangular or substantially rectangular shape when viewed in a direction perpendicular or substantially perpendicular to the substrate;
the first to the fourth terminals are provided on a same plane of the coil component; and
each of the terminals is arranged such that a direction from the first terminal to the second terminal and a direction from the third terminal to the fourth terminal cross each other.

3. The circuit device according to claim 1, wherein
the capacitor is connected in series to the third wiring line;
the substrate further includes a fourth wiring line electrically coupled to the capacitor on a side opposite to a side electrically coupled to the third wiring line; and
the fourth wiring line is grounded.

4. The circuit device according to claim 1, wherein the opening direction of the first coil and an opening direction of the second coil are perpendicular or substantially perpendicular to an arrangement direction of the capacitor.

5. The circuit device according to claim 1, wherein the third wiring line includes a portion connecting a connection portion between the third wiring line and the second terminal and a connection portion between the third wiring line and the third terminal with a straight line when viewed in a direction perpendicular to the substrate.

6. The circuit device according to claim 1, wherein
the coil component includes:
a bobbin including a body portion around which a wire is wound and flange portions provided at both ends of the body portion;
a first wire wound around the body portion and defining the first coil; and
a second wire wound around the body portion and defining the second coil; and
the first to the fourth terminals are defined in the flange portions.

7. The circuit device according to claim 6, wherein the opening direction of the first coil and an opening direction of the second coil are parallel or substantially parallel to a surface of the substrate on which the coil component is mounted.

8. The circuit device according to claim 6, wherein the first wire and the second wire are wound in a same direction.

9. The circuit device according to claim 6, wherein a total number of turns of the first wire and a total number of turns of the second wire are both one.

10. The circuit device according to claim 1, wherein
the coil component includes:
a housing;
the first coil located inside the housing and parallel or substantially parallel to a first main surface of the housing; and
the second coil located inside the housing and including the opening that overlaps with the opening of the first coil when viewed in a direction of the first main surface;
the first coil includes the first terminal extended from a first side surface side of the housing and the second terminal extended from a second side surface side of the housing;
the second coil includes the third terminal extended from the first side surface side of the housing and the fourth terminal extended from the second side surface side of the housing;
the first terminal and the third terminal extend in a direction of a second main surface along the first side surface side; and
the second terminal and the fourth terminal extend in the direction of the second main surface along the second side surface side.

11. The circuit device according to claim 10, wherein the opening direction of the first coil and an opening direction of the second coil are perpendicular or substantially perpendicular to a surface of the substrate on which the coil component is mounted.

12. The circuit device according to claim 10, wherein
the first coil, the first terminal, and the second terminal are integrally provided; and
the second coil, the third terminal, and the fourth terminal are integrally provided.

13. A filter circuit comprising:
the circuit device according to claim 1; and
the capacitor electrically coupled to the third wiring line of the circuit device.

14. The circuit device according to claim 1, wherein the first to the fourth terminals are respectively provided at individual ones of four corners of the coil component.

15. The circuit device according to claim 1, wherein a width of the third wiring line is approximately 1.3 to approximately 4 times a width of the second terminal and the third terminal.

16. The filter circuit according to claim 13, wherein
the coil component has a rectangular or substantially rectangular shape when viewed in a direction perpendicular or substantially perpendicular to the substrate;
the first to the fourth terminals are provided on a same plane of the coil component; and
each of the terminals is arranged such that a direction from the first terminal to the second terminal and a direction from the third terminal to the fourth terminal cross each other.

17. The filter circuit according to claim 13, wherein
the capacitor is connected in series to the third wiring line;
the substrate further includes a fourth wiring line electrically coupled to the capacitor on a side opposite to a side electrically coupled to the third wiring line; and
the fourth wiring line is grounded.

18. The filter circuit according to claim 13, wherein the opening direction of the first coil and an opening direction of the second coil are perpendicular or substantially perpendicular to an arrangement direction of the capacitor.

19. The filter circuit according to claim 13, wherein the third wiring line includes a portion connecting a connection portion between the third wiring line and the second terminal and a connection portion between the third wiring line and the third terminal with a straight line when viewed in a direction perpendicular to the substrate.

20. The filter circuit according to claim 13, wherein
the coil component includes:
a bobbin including a body portion around which a wire is wound and flange portions provided at both ends of the body portion;
a first wire wound around the body portion and defining the first coil; and
a second wire wound around the body portion and defining the second coil; and
the first to the fourth terminals are defined in the flange portions.
